(19) United States
(12) Patent Application Publication
(10) Pub. No.: US 2007/0187082 A1
(43) Pub. Date: Aug. 16, 2007

(54) Structural enhanced heat dissipating device

(76) Inventor: Li-Wei Fan Chiang, Taoyuan Hsien (TW)

Correspondence Address: Li-Wei Fan Chiang, 235 Chung - Ho, Box 8-24, Taipei, TW

(21) Appl. No.: 11/353,279

(22) Filed: Feb. 14, 2006

(51) Int. Cl. H05K 7/20

(52) U.S. Cl. 165/182; 165/104.33; 361/700

(57) ABSTRACT

A structural enhanced heat dissipating device comprises a plurality of heat dissipating fins; each fin having at least one through hole; each of the through hole being extended with a flange and a notch; and all the fins are aligned so that the through hole are aligned; at least one heat conductive tube; and the heat conductive tubes passing through the aligned through holes. By the flange, all the fins are spaced by a gap for dissipating heat; welding tins are filled into the notch for fixing the fin; and the heat conductive tubes are engaged with the flanges. Furthermore, at least one enhancing frames distributed on the fine and at a periphery of the flanges for enhancing the supporting strength of the flanges. At least one enhancing frame is distributed on the fine and at a periphery of the flanges for enhancing the supporting strength of the flanges;

### FIELD OF THE INVENTION

The present invention relates to a structural enhanced heat dissipating device, wherein the flanges are formed on the peripheries of a plurality of through holes on the heating dissipating fins of the heat dissipating device and thus all the fins are spaced by a gap for dissipating heat. Each through hole has a notch. The tin is filled into the notch so that the heat conductive tube can be firmly secured into the fins and thus has a preferred heat dissipating effect. Furthermore, enhancing frames are formed at a periphery of the through hole and thus have the effect of strengthening the structure of the heat dissipating fins.

### BACKGROUND OF THE INVENTION

In the prior art heat dissipating device, a plurality of fins are connected. There are many ways for connecting the plurality of fins. However in most of the prior arts, the fins are contact with one another so that heat is transferred from one fin to another fin, but the connection ways do not cause a preferred heat dissipation effect.

### SUMMARY OF THE INVENTION

Accordingly, the primary object of the present invention is to provide a structural enhanced heat dissipating device, wherein the flanges are formed on the peripheries of a plurality of through holes on the heating dissipating fins of the heat dissipating device and thus all the fins are spaced by a gap for dissipating heat. Each through hole has a notch. The tin is filled into the notch so that the heat conductive tube can be firmly secured into the fins and thus has a preferred heat dissipating effect. Furthermore, enhancing frames are formed at a periphery of the through hole and thus have the effect of strengthening the structure of the heat dissipating fins.

To achieve above objects, the present invention provides a structural enhanced heat dissipating device which comprises a plurality of heat dissipating fins; each fin having at least one through hole; each of the through hole being extended with a flange and a notch; and all the fins are aligned so that the through hole are aligned; at least one heat conductive tube; and the heat conductive tubes passing through the aligned through holes. By the flange, all the fins are spaced by a gap for dissipating heat; welding tins are filled into the notch for fixing the fin; and the heat conductive tubes are engaged with the flanges.

Furthermore, the present invention provides a structural enhanced heat dissipating device. The device comprises a plurality of heat dissipating fins; each fin having at least one through hole; each of the through hole being extended with a flange around an opening of the through hole; and all the fins are aligned so that the through hole are aligned; at least one heat conductive tube; and the heat conductive tubes passing through the aligned through holes; at least one enhancing frames distributed on the fine and at a periphery of the flanges for enhancing the supporting strength of the flanges. By the flange, all the fins are spaced by a gap for dissipating heat; and the heat conductive tubes are engaged with the flanges.

The various objects and advantages of the present invention will be more readily understood from the following detailed description when read in conjunction with the appended drawing.

### BRIEF DESCRIPTION OF THE DRAWINGS

FIG. 1 is an exploded perspective view showing the structure of a single one fin according to the present invention.

FIG. 2 is a schematic view of a fin in the present invention.

FIG. 3 is a schematic view about the assembly of the fins of the present invention.

FIG. 4 shows one embodiment of the present invention.

FIG. 5 shows another embodiment of the present invention.

FIG. 6 is the heat dissipating fins of FIG. 5.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

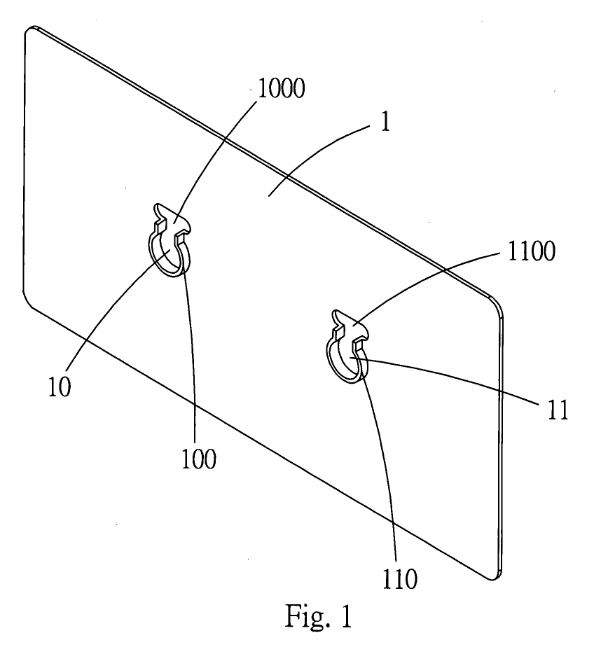

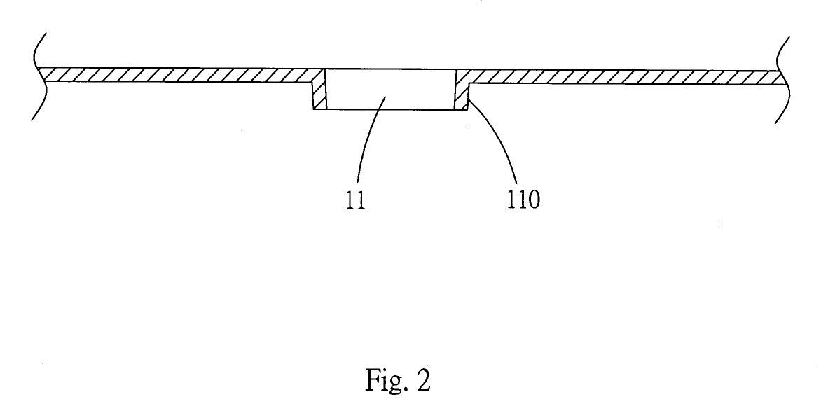

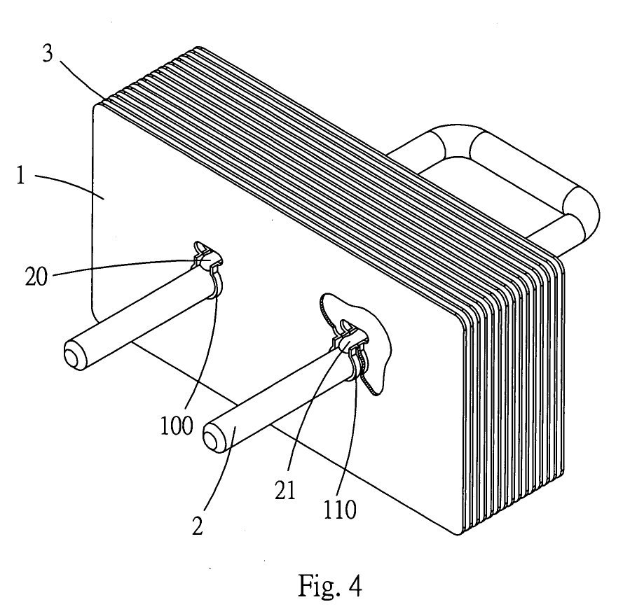

Referring to FIGS. 1 to 4, the structure of the present invention is illustrated. The present invention has the following elements.

A plurality of heat dissipating fins 1 are included. Each fin 1 has at least one through hole. In this embodiment, there are two through holes 10, 11 are illustrated. Each of the through hole 10, 11 is extended with a flange 100, 110 and a notch 1000, 1100 so that the through holes 10, 11 have a shape like a horse's hoof. In assembly, all the fins 1 are aligned so that the through holes 10, 11 are aligned.

At least one heat conductive tube 2 is included. In this embodiment, two heat conductive tubes 2 are illustrated. The heat conductive tubes 2 pass through the aligned through holes 10, 11.

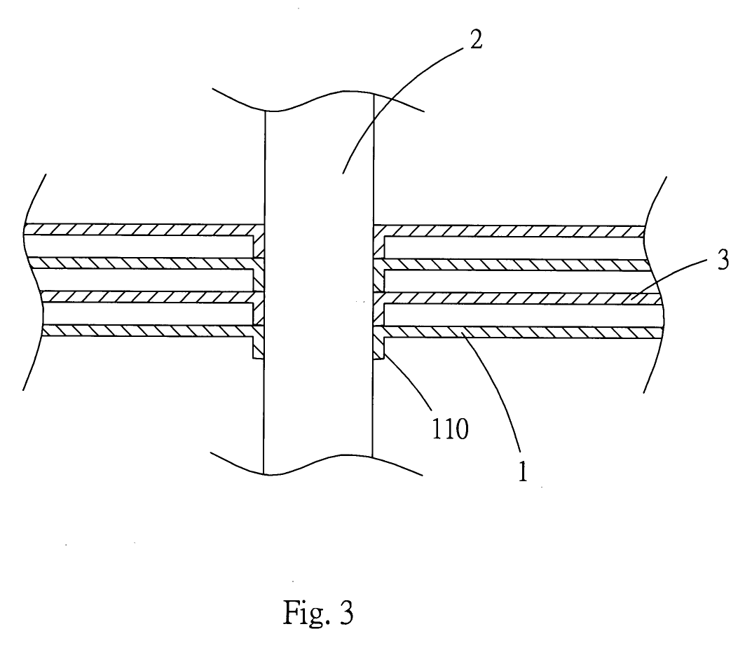

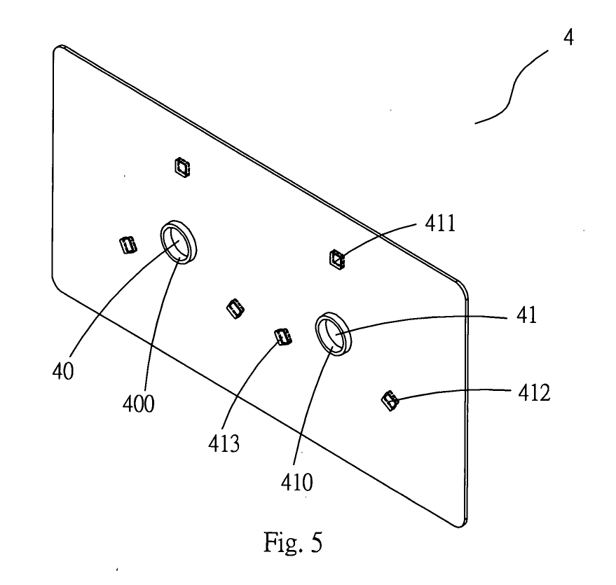

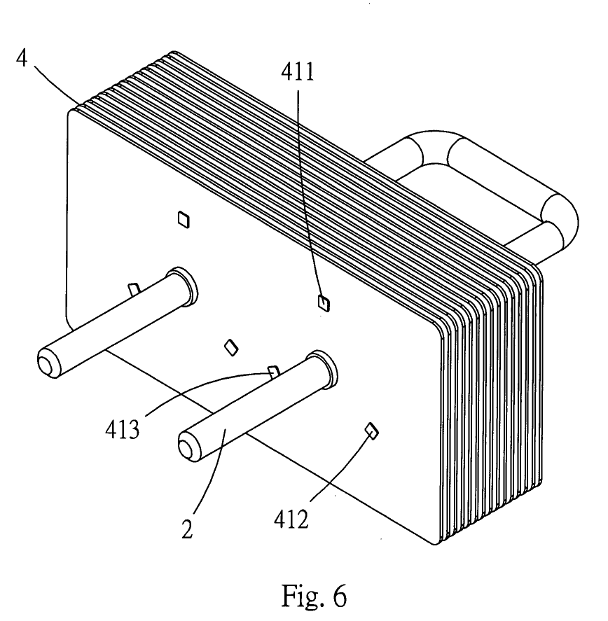

Referring to FIG. 3, by the flanges 100, 110, all the fins 1 are spaced by a gap for dissipating heat. Welding tins 20, 21 are filled into the notches 1000, 1100 for fixing the fin 1. The heat conductive tubes 2 are engaged with the flanges 100, 110. Referring to FIGS. 5 and 6, in the present invention, the fins 4 are formed with through holes 40, 41. An outer periphery of each through hole 40, 41 is formed with an annular flange 400, 410 for retaining the heat conductive tubes 2 passing through the through holes 40, 41. Each fin 4 is formed with at least one enhancing frame. In this embodiment, there are three enhancing frames 411, 412, 413 being illustrated. The enhancing frames 411, 412, 413 are distributed at the periphery of the flanges 410 for enhancing the supporting strength of the flanges 400, 410.

Advantages of the present invention will be described herein. In the present invention, the enhancing frame has the effect of strengthening the structure of the heat dissipating fins. The tin is filled into the notch so that the heat conductive tube can be firmly secured into the fins and thus has preferred heat dissipating effect.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A structural enhanced heat dissipating device comprising:
a plurality of heat dissipating fins; each fin having at least one through hole; each of the through hole being extended with a flange and a notch; and all the fins are aligned so that the through hole are aligned;
at least one heat conductive tube passing through the aligned through holes; and
wherein by the flange, all the fins are spaced by a gap for dissipating heat; welding tins are filled into the notch for fixing the fin; and the heat conductive tubes are engaged with the flanges.

2. A structural enhanced heat dissipating device comprising:
a plurality of heat dissipating fins; each fin having at least one through hole; each of the through hole being extended with a flange around an opening of the through hole; and all the fins are aligned so that the through hole are aligned;
at least one heat conductive tube; and the heat conductive tubes passing through the aligned through holes;
at least one enhancing frame distributed on the fine and at a periphery of the flanges for enhancing the supporting strength of the flanges; and
wherein by the flange, all the fins are spaced by a gap for dissipating heat; and the heat conductive tubes are engaged with the flanges.
